(19) United States
(12) Patent Application Publication
(10) Pub. No.: US 2002/0080569 A1
(43) Pub. Date: Jun. 27, 2002

(54) Computer

(75) Inventor: Wilhelm Neukam, Bobingen (DE)

Correspondence Address: OBLON SPIVAK MCCLELLAND MAIER & NEUSTADT PC, FOURTH FLOOR, 1755 JEFFERSON DAVIS HIGHWAY, ARLINGTON, VA, 22202, US

(73) Assignee: Fujitsu Siemens Computers GmbH, Muenchen (DE)

(21) Appl. No.: 09/987,861

(22) Filed: Nov. 16, 2001

(30) Foreign Application Priority Data
Dec. 27, 2000 (DE) 100 65 377.4

(51) Int. Cl. H05K 5/00

(52) U.S. Cl. 361/683

(57) ABSTRACT

The invention relates to a computer with a housing (1) that has outwardly protruding geometries (6), preventing any setting-up of the computer housing (1) in an undesirable position.

The invention relates to a computer with a housing that has a standing side and at least one other side that the computer can be placed on.

Normally, almost all computer housings are realized in such a way that, irrespective of whether desktop or tower housing, their geometry is essentially cuboid.

Because processors are constantly becoming more powerful, the heat released by the processor also increases. This is why the requirements for the thermal economy of the computer are becoming increasingly influential with regard to the construction of the computer.

For example, with modern, powerful computers it must be ensured for air conditioning reasons that the customer installs a unit only in a certain position. To date, the set-up directions and/or the set-up position of the computer have been specified in the operating instructions.

But operating instructions are often not read, or they are ignored, thereby leading to failures or a complete break-down of the computer in an undesirable set-up position that occurred only for reasons of air conditioning.

Therefore, the subject-matter of the present invention is to provide a solution that will ensure that a computer can only be installed in a predetermined position.

According to the invention, this objective is achieved by envisioning that the side of the computer onto which the computer should not be placed has an outwardly projecting geometry that makes any free placement of the computer on that side impossible.

The outwardly protruding geometry can be realized, for example, in the shape of an outwardly projecting arc-shaped curve, but also as an outwardly protruding slope, spike or peg.

Preferably, the outwardly protruding geometry is realized as a part made of a synthetic material that can be inserted in the housing into the appropriate bore holes by way of pegs.

The outwardly protruding geometry guarantees in a simple and cost-effective manner that any setting Up the computer in an undesirable position is prevented.

Subsequently, the invention will be explained based on an embodiment that is shown in the drawings.

The drawings show in:

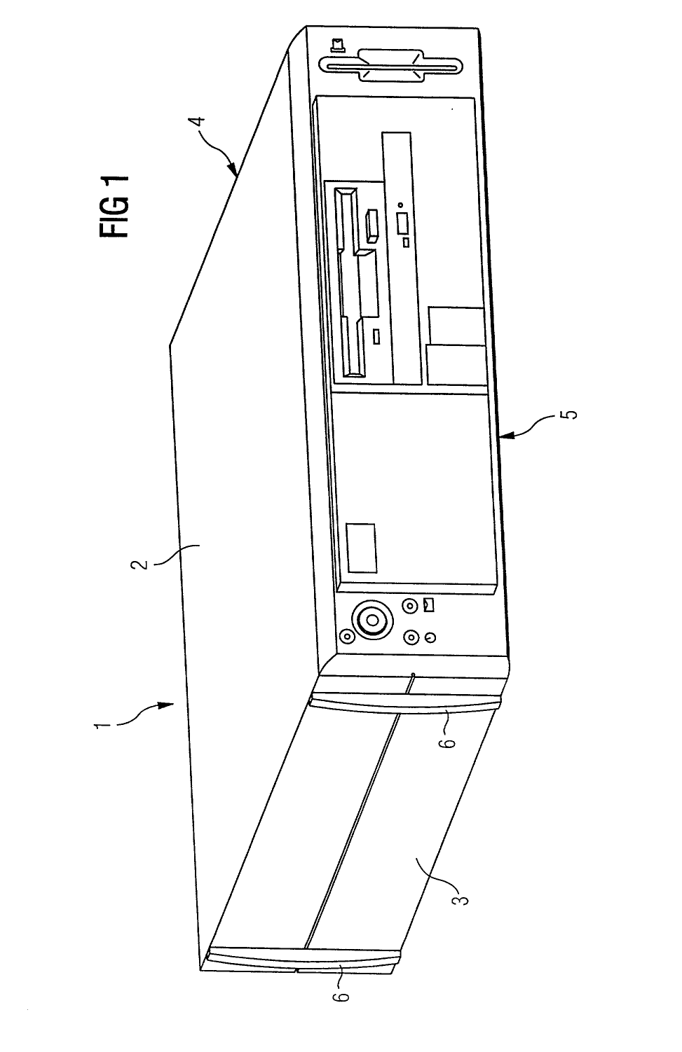

FIG. 1 an angular view of a desktop computer housing and in

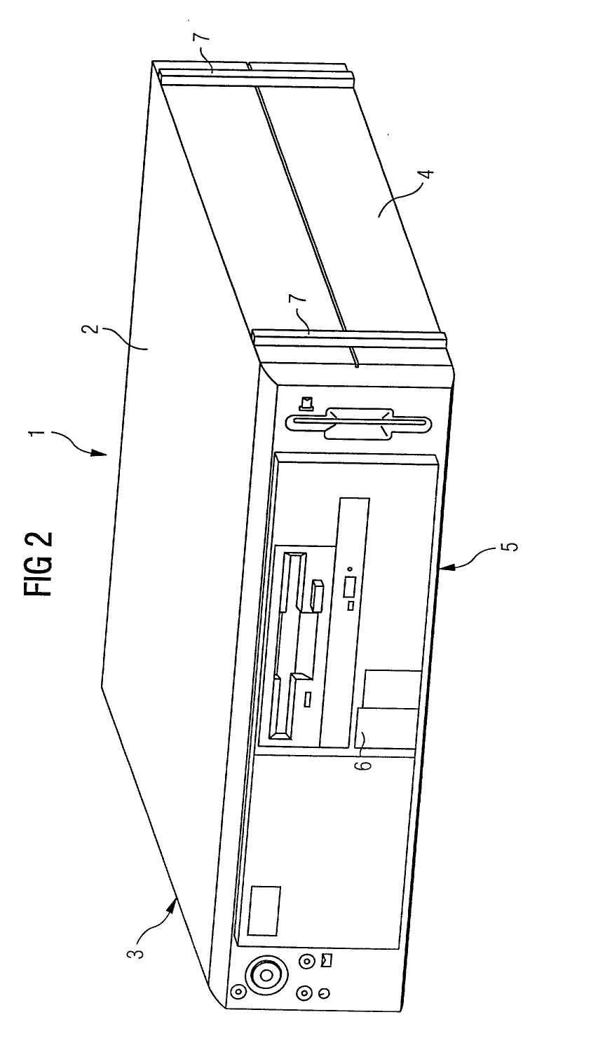

FIG. 2 another angular view of the desktop computer housing.

FIG. 1 shows an angular view of a computer with an essentially cuboid housing 1 with an upper side 2, two side surfaces 3 and 4 as well as a standing side S on the bottom side. For air-conditioning reasons within the housing, setting up the housing 1 on the housing side 3 is to be avoided.

According to the invention, outwardly protruding geometries 6, that do not permit a stable set-up on the side 3, are mounted on the housing side 3. In this instance, the outwardly protruding geometries 6 are realized as outwardly protruding curves, extending across the entire width of the side 3. The outwardly protruding geometries 6 can also be realized as outwardly protruding slopes, pegsr spikes etc. that will also prevent a stable set-up of the computer housing on this side.

The outwardly protruding geometries 6 are preferably manufactured from a synthetic material and are either screwed to the computer housing 1 or pushed into the appropriate bore holes in the computer housing 1 by way of pegs with snap hooks.

FIG. 2 shows the computer in accordance with FIG. 1 in a slightly rotated angular view, opening up a view on the side surface 4. To signal to the customer that set-up on the side surface 4 is permitted, it is equipped with plane, outwardly protruding geometries 7 that allow the placement of the device or of the computer housing 1 onto them.

1. Computer with a housing (1) that has a standing side (5) and at least one other side (3) onto which the computer can be placed wherein
the side (3) of the computer, onto which the computer should not be placed, is equipped with an outwardly protruding geometry (6) that does not permit the free placement of the computer on this side.

2. Computer as claimed in claim 1
wherein
the outwardly protruding geometry (6) is realized as rounded areas.

3. Computer as claimed in claim 1
wherein
the outwardly protruding geometry (6) is realized as an outwardly protruding slope.

4. Computer as claimed in claim 1
wherein
the outwardly protruding geometry (6) is realized as outwardly protruding pins, pegs or spikes.

5. Computer as claimed in one of the claims 1 to 4
wherein
the outwardly protruding geometry (6) is realized as a synthetic material part.

6. Computer as claimed in claim 5
wherein
the outwardly protruding geometry (6) can be fixed in place to the housing (1) of the computer using appropriate bore holes and by way of pins with snap hooks.
